(19) United States
(12) Patent Application Publication
(10) Pub. No.: US 2025/0311079 A1
(43) Pub. Date: Oct. 2, 2025

(54) EXTREME ULTRAVIOLET LIGHT GENERATION SYSTEM AND ELECTRONIC DEVICE MANUFACTURING METHOD

(71) Applicant: Gigaphoton Inc., Tochigi (JP)

(72) Inventor: Kenichi MIYAO, Oyama-shi (JP)

(73) Assignee: Gigaphoton Inc., Tochigi (JP)

(21) Appl. No.: 19/044,299

(22) Filed: Feb. 3, 2025

(30) Foreign Application Priority Data
Mar. 27, 2024 (JP) 2024-051077

(51) Int. Cl. H05G 2/00; G03F 1/44; G03F 7/00

(52) U.S. Cl. CPC H05G 2/0084; G03F 1/44; G03F 7/70033; G03F 7/705; G03F 7/70508; H05G 2/0027; H05G 2/0088

(57) ABSTRACT

An extreme ultraviolet light generation system includes a pulse laser light sensor measuring a pulse energy of the main pulse laser light, a target detection sensor generating a passage signal of the droplet target for irradiation with the main pulse laser light, an EUV light sensor measuring a pulse energy of the extreme ultraviolet light, and a processor. The processor includes a neural network receiving log data of the pulse energy obtained from the pulse laser light sensor, log data of an irradiation pulse interval of the main pulse laser light, and log data of the pulse energy obtained from the EUV light sensor, and generating information enabling to identify which state it is in among a normal state, a state of droplet target combining failure, a state of abnormal variation of droplet target intervals, and a state of abnormal relative position between the irradiation position and the mist-like target.

### CROSS-REFERENCE TO RELATED APPLICATIONS

The present application claims the benefit of Japanese Patent Application No. 2024-051077, filed on Mar. 27, 2024, the entire contents of which are hereby incorporated by reference.

### BACKGROUND

### 1. Technical Field

The present disclosure relates to an extreme ultraviolet light generation system and an electronic device manufacturing method.

### 2. Related Art

Recently, miniaturization of a transfer pattern in optical lithography of a semiconductor process has been rapidly proceeding along with miniaturization of the semiconductor process. In the next generation, microfabrication at 10 nm or less will be required. Therefore, it is expected to develop a semiconductor exposure apparatus that combines an apparatus for generating extreme ultraviolet (EUV) light having a wavelength of about 13 nm with a reduced projection reflection optical system.

As the EUV light generation apparatus, a laser produced plasma (LPP) type apparatus using plasma generated by irradiating a target substance with laser light has been developed.

### LIST OF DOCUMENTS

### Patent Documents

Patent Document 1: International Publication No. WO2022/201394
Patent Document 2: U.S. Pat. No. 10,395,356

### SUMMARY

An extreme ultraviolet light generation system according to an aspect of the present disclosure is configured to generate a mist-like target by irradiating, with prepulse laser light, a droplet target generated by combining a plurality of droplets, cause plasma to be generated by irradiating the mist-like target with main pulse laser light, and generate extreme ultraviolet light. The extreme ultraviolet light generation system includes a pulse laser light sensor configured to measure a pulse energy of the main pulse laser light, a target detection sensor configured to generate a passage signal of the droplet target for generating a trigger signal for irradiation with the main pulse laser light, an EUV light sensor configured to measure a pulse energy of the extreme ultraviolet light, and a processor. Here, the processor includes a neural network which receives, as input data, log data of the pulse energy obtained from the pulse laser light sensor, log data of an irradiation pulse interval of the main pulse laser light, and log data of the pulse energy obtained from the EUV light sensor and generates, as output data, information enabling to identify which state the extreme ultraviolet light generation system is in among a normal state, a state in which combining failure of the droplet targets is occurring, a state in which a variation of intervals between the droplet targets is abnormal, and a state in which a relative position between an irradiation position with the main pulse laser light and the mist-like target is abnormal.

An electronic device manufacturing method according to another aspect of the present disclosure includes generating extreme ultraviolet light using an extreme ultraviolet light generation system, outputting the extreme ultraviolet light to an exposure apparatus, and exposing a photosensitive substrate to the extreme ultraviolet light in the exposure apparatus to manufacture an electronic device. Here, the extreme ultraviolet light generation system is configured to generate a mist-like target by irradiating, with prepulse laser light, a droplet target generated by combining a plurality of droplets, cause plasma to be generated by irradiating the mist-like target with main pulse laser light, and generate the extreme ultraviolet light. The extreme ultraviolet light generation system includes a pulse laser light sensor configured to measure a pulse energy of the main pulse laser light, a target detection sensor configured to generate a passage signal of the droplet target for generating a trigger signal for irradiation with the main pulse laser light, an EUV light sensor configured to measure a pulse energy of the extreme ultraviolet light, and a processor. The processor includes a neural network which receives, as input data, log data of the pulse energy obtained from the pulse laser light sensor, log data of an irradiation pulse interval of the main pulse laser light, and log data of the pulse energy obtained from the EUV light sensor and generates, as output data, information enabling to identify which state the extreme ultraviolet light generation system is in among a normal state, a state in which combining failure of the droplet targets is occurring, a state in which a variation of intervals between the droplet targets is abnormal, and a state in which a relative position between an irradiation position with the main pulse laser light and the mist-like target is abnormal.

An electronic device manufacturing method according to an aspect of the present disclosure includes inspecting a defect of a mask by irradiating the mask with extreme ultraviolet light generated by an extreme ultraviolet light generation system, selecting the mask using a result of the inspection, and exposing and transferring a pattern formed on the selected mask onto a photosensitive substrate. Here, the extreme ultraviolet light generation system is configured to generate a mist-like target by irradiating, with prepulse laser light, a droplet target generated by combining a plurality of droplets, cause plasma to be generated by irradiating the mist-like target with main pulse laser light, and generate the extreme ultraviolet light. The extreme ultraviolet light generation system includes a pulse laser light sensor configured to measure a pulse energy of the main pulse laser light, a target detection sensor configured to generate a passage signal of the droplet target for generating a trigger signal for irradiation with the main pulse laser light, an EUV light sensor configured to measure a pulse energy of the extreme ultraviolet light, and a processor. The processor includes a neural network which receives, as input data, log data of the pulse energy obtained from the pulse laser light sensor, log data of an irradiation pulse interval of the main pulse laser light, and log data of the pulse energy obtained from the EUV light sensor and generates, as output data, information enabling to identify which state the extreme ultraviolet light generation system is in among a normal state, a state in which combining failure of the droplet targets is occurring, a state in which a variation of intervals between the droplet targets is abnormal, and a state in which a relative position between an irradiation position with the main pulse laser light and the mist-like target is abnormal.

### BRIEF DESCRIPTION OF THE DRAWINGS

An embodiment of the present disclosure will be described below merely as examples with reference to the accompanying drawings.

FIG. 1 is a view showing an EUV light generation system according to a comparative example.

FIG. 2 is a diagram showing the detailed configuration of a target image imaging unit.

FIG. 3 is a diagram showing an imaging region of the target image imaging unit.

FIG. 4 is a diagram for explaining an arrangement example of EUV light sensors.

FIG. 5 is a diagram of the arrangement of the EUV light sensors as viewed from an X-axis direction.

FIG. 6 is a flowchart showing an example of operation of the EUV light generation: system according to the comparative example.

FIG. 7 is a flowchart showing details of processing applied to step S10 of FIG. 6.

FIG. 8 is a flowchart showing details of processing applied to step S60 of FIG. 6.

FIG. 9 is a view showing the EUV light generation system according to a first embodiment.

FIG. 10 is a flowchart showing an example of operation of the EUV light generation system according to the first embodiment.

FIG. 11 is a graph showing an example of log data of the pulse energy of main pulse laser light.

FIG. 12 is a graph showing an example of log data of an irradiation pulse interval of the main pulse laser light.

FIG. 13 is a diagram showing an example of log data of the EUV light pulse energy detected by one of the EUV light sensors.

FIG. 14 is a flowchart showing details of processing applied to step S25 of FIG. 10.

FIG. 15 is a diagram showing display example 1 of an estimation result on a terminal.

FIG. 16 is a diagram showing display example 2 of the estimation result on the terminal.

FIG. 17 is a flowchart showing details of processing applied to step S55 of FIG. 10.

FIG. 18 is a diagram showing the configuration of a learning model used in the first embodiment.

FIG. 19 is a flowchart showing a generation method of the learning model.

FIG. 20 schematically shows the configuration of an exposure apparatus connected to the EUV light generation system.

FIG. 21 schematically shows the configuration of an inspection apparatus connected to the EUV light generation system.

### DESCRIPTION OF EMBODIMENTS

### Contents

1. Overall description of EUV light generation system according to comparative example
   1.1 Configuration
   1.2 Operation
2. Problem
3. First Embodiment
   3.1 Configuration
   3.2 Operation
   3.3 Generation method of learning model
      3.3.1 Configuration of learning model
      3.3.2 Generation flow of learning model
   3.4 Modification
   3.5 Effect
4. Exposure apparatus and inspection apparatus
5. Others

Hereinafter, an embodiment of the present disclosure will be described in detail with reference to the drawings. The embodiment described below show some examples of the present disclosure and do not limit the contents of the present disclosure. Also, all configurations and operation described in the embodiment are not necessarily essential as configurations and operation of the present disclosure. Here, the same components are denoted by the same reference numeral, and duplicate description thereof is omitted.

### 1. OVERALL DESCRIPTION OF EUV LIGHT GENERATION SYSTEM ACCORDING TO COMPARATIVE EXAMPLE

### 1.1 Configuration

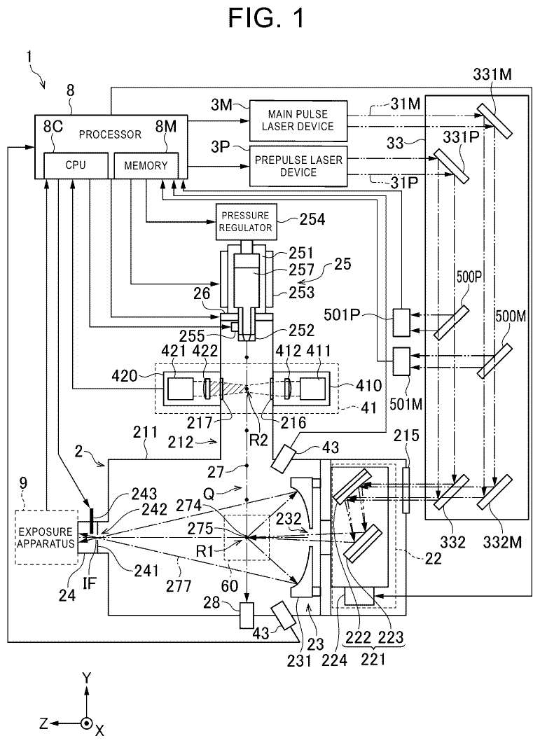

FIG. 1 is a view showing an EUV light generation system 1 according to a comparative example. The comparative example of the present disclosure is an example recognized by the applicant as known only by the applicant, and is not a publicly known example admitted by the applicant. The EUV light generation system 1 is an LPP type EUV light generation apparatus. The EUV light generation system 1 includes a prepulse laser device 3P and a main pulse laser device 3M, and generates a target in a mist form by irradiating a target in a droplet form with prepulse laser light 31P output from the prepulse laser device 3P. The target in a droplet form is called a droplet target 27. The target in a mist form is referred to as a mist-like target 274.

The EUV light generation system 1 generates plasma 275 by irradiating the mist-like target 274 with main pulse laser light 31M output from the main pulse laser device 3M. The generated plasma 275 emits EUV light 277. The EUV light generation system 1 collects the EUV light 277 and outputs the EUV light 277 to an exposure apparatus 9 that is an external apparatus of the EUV light generation system 1.

The prepulse laser device 3P is, for example, a YAG laser device or a laser device using Nd:YVO₄. The main pulse laser device 3M is, for example, a CO₂ laser device. Alternatively, the main pulse laser device 3M may be a YAG laser device or a laser device using Nd:YVO₄.

The EUV light generation system 1 further includes a chamber 2, a laser light transmission optical system 33, laser light sensors 501P, 501M, a laser light concentrating optical system 22, an EUV light concentrating optical system 23, a connection portion 24, a target supply unit 25, a stage 26, a target collector 28, a target detection sensor 41, a target image imaging unit 60, a plurality of EUV light sensors 43, and a processor 8.

The processor 8 is a processing device including a central processing unit (CPU) that executes various control programs and a memory 8M that stores the various control programs. The processor 8 is specifically configured or programmed to perform various processes included in the present disclosure. The processor 8 generally controls operation of each component of the EUV light generation system 1 based on various commands from the exposure apparatus 9 that is an external apparatus.

The chamber 2 is a container in which the plasma 275 is generated from the mist-like target 274 by irradiating the mist-like target 274 generated therein with the main pulse laser light 31M and the EUV light 277 is generated. A wall 211 of the chamber 2 forms the internal space of the chamber 2 and isolates the internal space of the chamber 2 from the outside. The wall 211 is provided with a window 215 for introducing the prepulse laser light 31P and the main pulse laser light 31M into the chamber 2. The chamber 2 also includes a target supply path 212 for supplying the droplet target 27 into the chamber 2.

The laser light transmission optical system 33 is an optical system that introduces the prepulse laser light 31P and the main pulse laser light 31M output from the prepulse laser device 3P and the main pulse laser device 3M into the chamber 2 through the window 215. The laser light transmission optical system 33 is arranged on the optical paths of the prepulse laser light 31P and the main pulse laser light 31M outside the chamber 2 and between the window 215 and each of the prepulse laser device 3P and the main pulse laser device 3M.

The laser light transmission optical system 33 includes a high reflection mirror 331P and a combiner 332 that transmit the prepulse laser light 31P, and a high reflection mirror 331M and a high reflection mirror 332M that transmit the main pulse laser light 31M. Each of the optical elements is mounted on a stage (not shown) that adjusts at least one of the position and the posture thereof. The operation of the stages is controlled by the CPU 8C. The laser light transmission optical system 33 further includes a beam splitter 500P and a beam splitter 500M.

The beam splitter 500P is arranged on the optical path of the prepulse laser light 31P, and reflects a part of the prepulse laser light 31P and transmits the other part. The laser light sensor 501P detects the energy of the part of the prepulse laser light 31P reflected by the beam splitter 500P.

The beam splitter 500M is arranged on the optical path of the main pulse laser light 31M, and reflects a part of the main pulse laser light 31M and transmits the other part. The laser light sensor 501M detects the energy of the part of the main pulse laser light 31M reflected by the beam splitter 500M.

The laser light concentrating optical system 22 is an optical system that concentrates the prepulse laser light 31P and the main pulse laser light 31M introduced into the chamber 2 through the window 215 on the plasma generation region R1, and is arranged inside the chamber 2. The laser light concentrating optical system 22 includes a laser light concentrating mirror 221 and a manipulator 224.

The laser light concentrating mirror 221 is mounted on the manipulator 224. The laser light concentrating mirror 221 is configured using an off axis parabolic mirror 222 and a planar mirror 223.

The manipulator 224 is a mechanism that adjusts at least one of the position and the posture of the laser light concentrating mirror 221. The manipulator 224 adjusts at least one of the position and the posture of the laser light concentrating mirror 221 so that the droplet target 27 is irradiated with the prepulse laser light 31P in the plasma generation region R1 and the mist-like target 274 is irradiated with the main pulse laser light 31M.

Driving of the manipulator 224 is controlled by the CPU 8C. The manipulator 224 may be a mechanism that moves the laser light concentrating mirror 221 in a direction along at least one of an X axis and a Y axis. The manipulator 224 may be a mechanism that moves the laser light concentrating mirror 221 in a direction along a Z axis in addition to the X axis and the Y axis. The manipulator 224 may be a stage that is a mechanism for adjusting at least one of the position and the posture of the laser light concentrating mirror 221.

Regarding the directions of the X axis, the Y axis, and the Z axis, a direction in which the EUV light 277 is output from the chamber 2 toward the exposure apparatus 9 is defined as a direction of the Z axis. The X axis and the Y axis are perpendicular to the Z axis and are perpendicular to each other. A center axis direction of a nozzle 252, which will be described later, of the target supply unit 25 that outputs a target substance 257 into the chamber 2 is defined as a direction of the Y axis. The direction of the Y axis is a direction of a target trajectory Q described later.

The EUV light concentrating optical system 23 is an optical system that collects the EUV light 277 and concentrates the EUV light 277 on the intermediate focal point IF. The EUV light concentrating optical system 23 is arranged inside the chamber 2. The EUV light concentrating optical system 23 includes an EUV light concentrating mirror 231.

The EUV light concentrating mirror 231 reflects the EUV light 277 emitted from the plasma 275 in the plasma generation region R1. The EUV light concentrating mirror 231 concentrates the reflected EUV light 277 on the intermediate focal point IF located in the connection portion 24. A reflection surface of the EUV light concentrating mirror 231 is formed of a multilayer reflection film in which, for example, molybdenum and silicon are alternately stacked. The reflection surface of the EUV light concentrating mirror 231 is formed of, for example, a part of a spheroidal surface having a first focal point and a second focal point.

The EUV light concentrating mirror 231 is arranged such that the first focal point is located in the plasma generation region R1 and the second focal point is located at the intermediate focal point IF. A through hole 232 is formed at the center of the EUV light concentrating mirror 231. The through hole 232 is a hole through which the prepulse laser light 31P and the main pulse laser light 31M reflected by the laser light concentrating mirror 221 pass toward the plasma generation region R1.

The connection portion 24 is a connection portion between the chamber 2 and the exposure apparatus 9. A wall 241 and an EUV shutter 243 are provided in the connection portion 24. An aperture 242 is formed in the wall 241. The aperture 242 is formed so as to be located at the intermediate focal point IF. The EUV shutter 243 is arranged so as to be able to move into and out of the optical path of the EUV light 277 so that the output of the EUV light 277 can be adjusted. Opening and closing of the EUV shutter 243 is controlled by the CPU 8C.

The target supply unit 25 is a device that melts the target substance 257, which is a metal material to form the droplet target 27 to be supplied into the chamber 2, and outputs the target substance 257 toward the plasma generation region R1 in the form of a droplet. The target supply unit 25 is a device that outputs the droplet target 27 with a so-called continuous jet method. The droplet target 27 supplied by the target supply unit 25 is formed of a metal material. The metal material forming the droplet target 27 is material including tin, terbium, gadolinium, or a combination of any two or more thereof. A preferable metal material is tin.

The target supply unit 25 is configured using a tank 251, the nozzle 252, a heater 253, a pressure regulator 254, and a piezoelectric element 255. Operation of the target supply unit 25 is controlled by the CPU 8C. The target supply unit 25 is mounted on the stage 26.

The stage 26 is a mechanism that adjusts the position or the posture of the target supply unit 25. The stage 26 is a mechanism that moves the target supply unit 25 in at least one axial direction of the X axis, the Y axis, and the Z axis. The stage 26 is a mechanism that adjusts the position of the target supply unit 25 so that the droplet target 27 output from the target supply unit 25 is supplied to a target misting region Rmist defined in advance. Driving of the stage 26 is controlled by the CPU 8C.

The target collector 28 is a device that collects the droplet targets 27 that have not been irradiated with the prepulse laser light 31P and the main pulse laser light 31M among the droplet targets 27 output into the chamber 2. The target collector 28 is arranged on the wall 211 of the chamber 2 on an extension line of the target trajectory Q.

The target detection sensor 41 is a sensor that detects the droplet target 27 passing through a target detection region R2. The target detection region R2 is a region at a predetermined position on the target trajectory Q in the target supply path 212. The target detection sensor 41 includes an illumination unit 410 and a detection unit 420.

The illumination unit 410 and the detection unit 420 are connected to the wall 211 of the chamber 2 configuring the target supply path 212 through the window 216 and the window 217, respectively. The illumination unit 410 and the detection unit 420 are arranged to face each other across the target detection region R2 on the target trajectory Q. The illumination unit 410 and the detection unit 420 are arranged such that an illumination optical axis of the illumination unit 410 and a detection optical axis of the detection unit 420 pass through the target detection region R2 substantially coaxially with each other, as shown in FIG. 1. The illumination optical axis of the illumination unit 410 is an optical path axis of the illumination light output from the illumination unit 410 toward the target detection region R2. The detection optical axis of the detection unit 420 is an optical path axis of the illumination light detected by the detection unit 420 among the illumination light output from the illumination unit 410 toward the target detection region R2.

The illumination unit 410 outputs the illumination light toward the target detection region R2 so as to illuminate the droplet target 27 passing through the target detection region R2. The illumination unit 410 is configured using a light source 411 and an illumination optical system 412. The detection unit 420 is electrically connected to the CPU 8C, detects the light intensity of the illumination light output so as to illuminate the droplet target 27 passing through the target detection region R2, and transmits a detection signal to the CPU 8C. This detection signal may be referred to as a passage timing signal. The detection unit 420 is configured using an optical sensor 421 and a light receiving optical system 422.

The target image imaging unit 60 images the droplet target 27 having passed through the target detection region R2 and traveling toward the plasma generation region R1 and the mist-like target 274.

The EUV light sensors 43 are sensors that measure the energy of the EUV light 277 emitted from the plasma 275. The plurality of EUV light sensors 43 measure the energy of the EUV light 277 from different directions from each other, and transmit the measurement values to the CPU 8C. Operation of the plurality of EUV light sensors 43 is controlled by the CPU 8C.

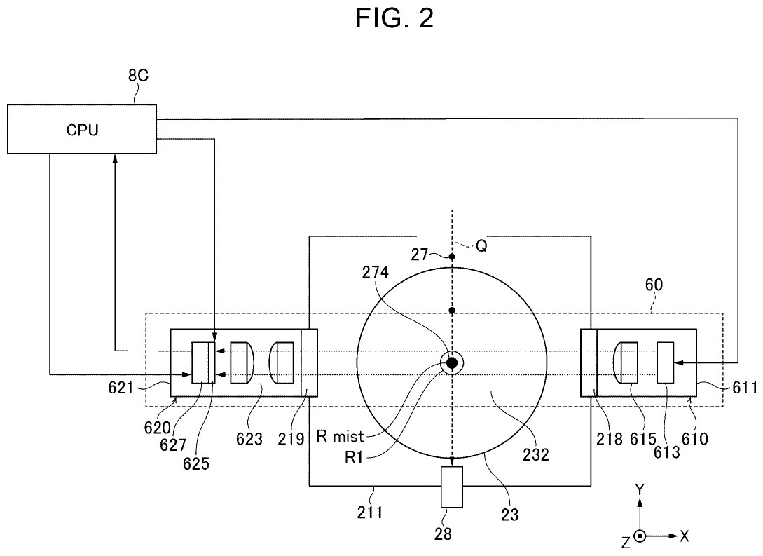

FIG. 2 is a diagram showing the detailed configuration of the target image imaging unit 60. FIG. 2 shows a case in which the configuration around the target image imaging unit 60 is viewed from a −Z direction.

The target image imaging unit 60 includes an illumination unit 610 and an imaging unit 620. The illumination unit 610 is arranged on the side opposite to the imaging unit 620 with respect to the target trajectory Q of the droplet target 27. The direction in which the illumination unit 610 and the imaging unit 620 are arranged is perpendicular to the target trajectory Q in FIG. 2, but may not be perpendicular. The illumination unit 610 and the imaging unit 620 are attached to the wall 211 at the outside of the chamber 2, the illumination unit 610 is arranged coaxially with a window 218 provided in the wall 211, and the imaging unit 620 is arranged coaxially with a window 219 provided in the wall 211.

The illumination unit 610 includes a container 611, and a light source 613 and an illumination optical system 615 that are accommodated in the container 611. The light source 613 is, for example, a flash lamp that outputs light having a plurality of wavelengths. The illumination optical system 615 includes a collimator lens. The output timing of illumination light output from the light source 613 toward the droplet target 27 and the mist-like target 274 in the plasma generation region R1 is controlled by the CPU 8C.

The imaging unit 620 includes a container 621, and an imaging optical system 623, a shutter 625, and an imaging body unit 627 that are accommodated in the container 621. The imaging optical system 623 includes a first lens and a second lens. The imaging body unit 627 is, for example, a charge-coupled device (CCD).

Upon receiving the passage timing signal from the target detection sensor 41, the CPU 8C outputs an imaging trigger signal to each of the shutter 625 and the imaging body unit 627 with a delay of a predetermined delay time from the input of the passage timing signal. Hereinafter, the imaging trigger signal for the shutter 625 may be referred to as a shutter trigger signal, and the imaging trigger signal for the imaging body unit 627 may be referred to as an imaging trigger signal. Upon receiving the shutter trigger signal, the shutter 625 opens for an extremely short time and then closes. The imaging body unit 627 receives an imaging trigger signal and receives the illumination light while the shutter 625 is open. Then, the imaging body unit 627 images the droplet target 27 and the mist-like target 274 to generate image data, and outputs the image data to the CPU 8C as an electric signal.

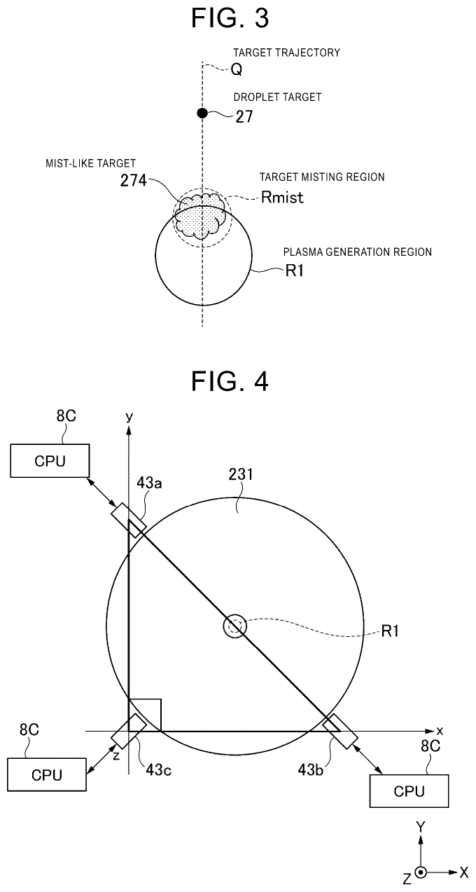

FIG. 3 is a diagram showing an imaging region of the target image imaging unit 60.

The droplet target 27 travels along the target trajectory Q from top to bottom in FIG. 3. A region in which the droplet target 27 is misted is referred to as the target misting region Rmist. The positional relationship among the target misting region Rmist, the plasma generation region R1, and a subsequent droplet target 27 is, for example, as shown in FIG. 3.

Here, in FIG. 3, only one subsequent droplet target 27 at the timing when the mist-like target 274 is generated is shown, but the target image imaging unit 60 may have an imaging region capable of imaging a plurality of droplet targets 27 traveling along the target trajectory Q.

The plasma generation region R1 includes a region located below the target misting region Rmist (in a −Y direction) and overlapping with the target misting region Rmist. The center of the target misting region Rmist is included in the plasma generation region R1.

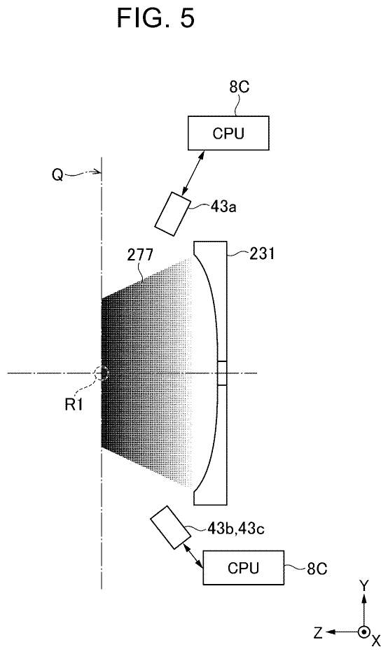

FIG. 4 is a diagram for explaining an arrangement example of the EUV light sensors 43. FIG. 5 is a diagram of the arrangement of the EUV light sensors 43 shown in FIG. 4 as viewed from an X-axis direction. As shown in FIGS. 4 and 5, the plurality of EUV light sensors 43 are configured by, for example, EUV light sensors 43a to 43c. The EUV light sensors 43a to 43c are arranged on the wall 211 of the chamber 2 so as to face the plasma generation region R1 respectively from different directions. The EUV light sensors 43a to 43c are arranged so as not to block the optical path of the EUV light 277 reflected by the EUV light concentrating mirror 231. The EUV light sensors 43a to 43c are arranged along the outer circumferential edge of the EUV light concentrating mirror 231. The EUV light sensors 43a to 43c are arranged at equal distance respectively from the plasma generation region R1 so that the difference in energy measured thereby is small when the plasma 275 is generated in the plasma generation region R1.

The plurality of EUV light sensors 43a to 43c are arranged at positions where the centroid position of the EUV light 277 is easily evaluated. For example, the EUV light sensors 43a to 43c are arranged respectively at the vertices of an isosceles right triangle as shown in FIG. 4. The isosceles right triangle shown in FIG. 4 is an isosceles right triangle having the middle point of the long side located in the plasma generation region R1, the vertical angle located on the Z axis, and the two short sides arranged along the X axis and the Y axis, respectively. The EUV light sensor 43a is an EUV light sensor arranged at an apex located on the Y axis of the isosceles right triangle shown in FIG. 4. The EUV light sensor 43b is an EUV light sensor arranged at an apex located on the X axis of the isosceles right triangle shown in FIG. 4. The EUV light sensor 43c is an EUV light sensor arranged at an apex located on the Z axis of the isosceles right triangle shown in FIG. 4.

The centroid position of the EUV light 277 is the centroid position of an energy distribution of the EUV light 277. That is, the centroid position of the EUV light 277 is the position of a weighted average in the energy distribution of the EUV light 277. Specifically, the centroid position of the EUV light 277 is a spatial position specified from a plurality of measurement values obtained by measuring the energy of the EUV light 277 by the plurality of EUV light sensors 43a to 43c. The centroid position of the EUV light 277 is an index that reflects the irradiation position of the main pulse laser light 31M on the mist-like target 274. The irradiation position of the main pulse laser light 31M on the mist-like target 274 is determined according to the centroid position of the EUV light 277.

### 1.2 Operation

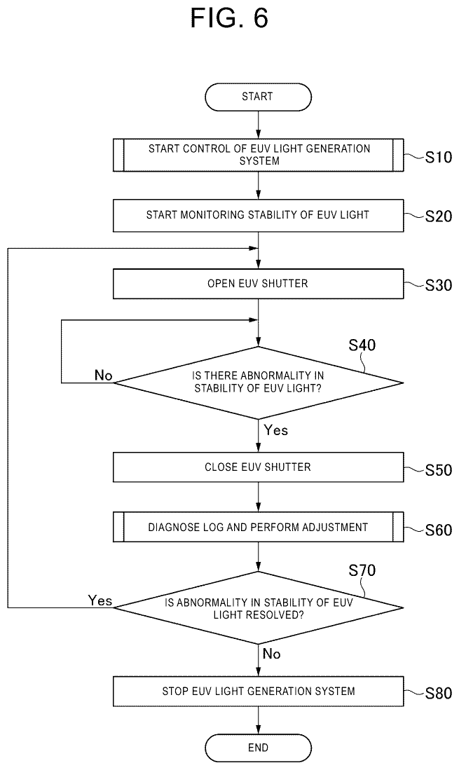

FIG. 6 is a flowchart showing an example of operation of the EUV light generation system 1 according to the comparative example.

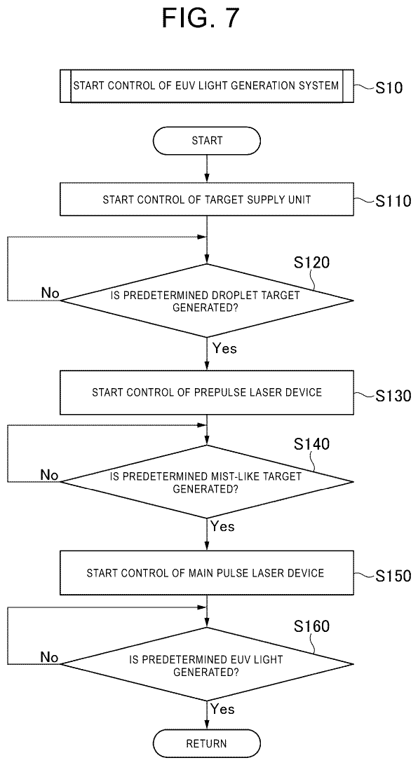

In step S10, the CPU 8C activates the respective devices configuring the EUV light generation system 1 and starts control of the respective devices so that predetermined EUV light 277 is generated. Individual control of each device is started by the CPU 8C so as to achieve the target value set in advance for each device, and starts operation of recording, in time series in the memory 8M, data indicating a variation in the distance between adjacent droplet targets 27, data indicating the size of the droplet target 27, and data indicating the irradiation position of the main pulse laser light 31M on the mist-like target 274. Hereinafter, the data recorded in time series is referred to as log data. At this time, the EUV shutter 243 is closed, and the EUV light 277 is not output to the outside of the EUV light generation system 1. Details of the process of step S10 will be described later (FIG. 7).

In step S20, the CPU 8C starts monitoring the EUV light generation system 1. The monitoring is performed for the stability of the pulse energy of the EUV light 277. The pulse energy of the EUV light 277 may be referred to as an EUV pulse energy. The method of evaluating the stability of the EUV light 277 will be described later.

In step S30, the CPU 8C opens the EUV shutter 243 and outputs the EUV light 277 to the exposure apparatus 9.

In step S40, the CPU 8C performs determination corresponding to the monitoring started in step S20. That is, the CPU 8C determines whether or not there is abnormality in the stability of the EUV light 277. As a result of the determination, when there is no abnormality, the process of step S40 is repeated. In the determination of step S40, when the stability of the pulse energy of the EUV light 277 is lower than a predetermined value, the CPU 8C determines that there is abnormality in the stability of the EUV light 277 and proceeds to step S50. Details of step S40 will be described later.

In step S50, the CPU 8C closes the EUV shutter 243 and stops the output of the EUV light 277. Here, generation of the EUV light 277 is continued even in a state in which the EUV shutter 243 is closed.

In step S60, the CPU 8C diagnoses log data of the EUV light generation system 1, and finely adjusts some devices so that the stability of the pulse energy of the EUV light 277 returns to the predetermined value. After the fine adjustment, the CPU 8C waits until log data required to determine the stability of the EUV light 277 is collected. Details thereabove will be described later.

In step S70, the CPU 8C determines whether or not abnormality in the stability of the EUV light 277 has been resolved. After performing the fine adjustment in step S60, the CPU 8C generates a new monitoring result, and in the determination of step S70, when it is determined that abnormality in the stability of the EUV light 277 has been resolved, processing returns to step S30 and the EUV light 277 is output to the outside.

On the other hand, when the CPU 8C determines that abnormality in the stability of the EUV light 277 has not been resolved as a result of the determination of step S70, processing proceeds to step S80.

In step S80, the CPU 8C stops the EUV light generation system 1. After step S80, the flowchart of FIG. 6 is ended.

### Detailed Description of Step S10

FIG. 7 is a flowchart showing details of processing applied to step S10 of FIG. 6. In an EUV light generation system control starting step (step S10) shown in FIG. 7, generation of log data is also started at the time when the control is started.

In step S110, the CPU 8C activates the target supply unit 25, the target detection sensor 41, the target image imaging unit 60, and the EUV light sensors 43, and starts the following control.

The CPU 8C controls the target supply unit 25 so that the droplet target 27 is output from the target supply unit 25 toward the target misting region Rmist. Specifically, the CPU 8C heats the heater 253 of the target supply unit 25 to a temperature equal to or higher than the melting point of the target substance 257, and causes the target substance 257 in a solid state contained in the tank 251 of the target supply unit 25 to melt.

When the target substance 257 is tin, since the melting point of tin is 232° C., the CPU 8C heats the heater 253 at a temperature of, for example, 250° C. or higher and 290° C. or lower. The CPU 8C controls the pressure regulator 254 of the target supply unit 25 to apply a predetermined pressure to the target substance 257 in the tank 251 so that the target substance 257 in the tank 251 is continuously output from the nozzle 252 at a predetermined velocity. Next, the CPU 8C vibrates the piezoelectric element 255 in a predetermined waveform so that the target substance 257 output from the nozzle 252 is turned into droplets and a plurality of droplets are combined to generate a combined droplet having a predetermined diameter and a predetermined cycle. Hereinafter, the combined droplet is also referred to as a droplet target 27.

The droplet target 27 output into the chamber 2 passes through the target detection region R2. The target detection sensor 41 detects a timing at which the droplet target 27 passes through the target detection region R2 and generates a passage timing signal. Specifically, the light source 411 of the illumination unit 410 outputs illumination light toward the target detection region R2 via the illumination optical system 412 so as to illuminate the droplet target 27 passing through the target detection region R2. The optical sensor 421 of the detection unit 420 detects, via the light receiving optical system 422, the illumination light output to the target detection region R2, thereby detecting the droplet target 27 passing through the target detection region R2. The light intensity of the illumination light detected by the optical sensor 421 may decrease at the timing at which the droplet target 27 passes through the target detection region R2. The optical sensor 421 generates a passage timing signal which is an output signal corresponding to a change in the light intensity of the detected illumination light, and transmits the passage timing signal to the CPU 8C.

The CPU 8C determines the timing at which the passage timing signal becomes lower than a predetermined threshold as the timing at which the droplet target 27 passes through the target detection region R2. The CPU 8C generates a target detection signal indicating that the droplet target 27 passes through the target detection region R2 at the timing at which the passage timing signal becomes lower than the predetermined threshold. The CPU 8C controls the piezoelectric element 255 so that the frequency of the target detection signal becomes a predetermined frequency.

The droplet target 27 that has passed through the target detection region R2 is supplied to the target misting region Rmist. The target image imaging unit 60 generates image data in which a region including the target misting region Rmist is imaged, and transmits the image data to the CPU 8C. The CPU 8C defines the target trajectory Q of the droplet target 27 from the image data, and calculates a drive amount of the stage 26 required for the target trajectory Q to pass through the target misting region Rmist. Then, the CPU 8C controls the stage 26 so that the target trajectory Q passes through the target misting region Rmist based on the drive amount.

Further, the CPU 8C generates log data indicating the variation in the distance between adjacent droplet targets 27 from the image data, and records the log data in the memory 8M. The variation in the distance between adjacent droplet targets 27 is recorded as a variation σ of the time interval (variation of the time difference) of the droplet targets 27 reaching the target misting region Rmist. The variation σ of the time interval is defined as follows.

The variation σ of the time interval between the time when a preceding droplet target 27 reaches the target misting region Rmist and the time when the droplet target 27 traveling immediately thereafter reaches the target misting region Rmist is calculated by, for example, the following expression.

Variation σ of time interval[%]=(σst/μt)×100

Here, σst is the standard deviation of a plurality of time intervals included in a unit time. Further, μt is an average value of the plurality of time intervals included in the unit time. The unit time is several seconds, for example, about 1 to 5 seconds. As an index for evaluating the variation of the time interval of the droplet targets 27, for example, n times of the standard deviation σst may be used as an index instead of the variation σ of the time interval. Here, n is an arbitrary positive number. Further, the CPU 8C generates log data indicating the size of the droplet target 27 in the X direction and the size of the droplet target in the Y direction from the image data, and records the log data in the memory 8M.

In step S120, the CPU 8C determines whether or not a predetermined droplet target 27 is generated. Specifically, the CPU 8C performs determination of whether or not the droplet target 27 supplied to the target misting region Rmist passes through the predetermined target trajectory Q, and determination of whether or not the droplet target 27 has a predetermined size. When it is determined that either of the conditions is not satisfied as a result of the determination of step S120, the process of step S120 is repeated. When it is determined that both conditions are satisfied as a result of the determination of step S120, processing proceeds to step S130.

In step S130, the CPU 8C starts control of the prepulse laser device 3P. That is, the CPU 8C activates the prepulse laser device 3P and the stage of the high reflection mirror 331, and starts the following control.

The CPU 8C transmits a trigger signal that triggers the output of the prepulse laser light 31P to the prepulse laser device 3P at a timing delayed by a delay time Tdp from the timing at which the target detection signal is generated, and causes the prepulse laser device 3P to output the prepulse laser light 31P.

The delay time Tdp is a time for matching the timing at which the prepulse laser light 31P is concentrated on the target misted region Rmist with the timing at which the droplet target 27 is supplied to the target misting region Rmist. The delay time Tdp is a time calculated by the CPU 8C from the distance between the target misting region Rmist and the target detection region R2 and the frequency of the target detection signal.

Upon receiving the trigger signal, the prepulse laser device 3P outputs the prepulse laser light 31P. The prepulse laser light 31P output from the prepulse laser device 3P is reflected by the high reflection mirror 331P and the combiner 332 of the laser light transmission optical system 33, is transmitted through the window 215, and is introduced into the chamber 2. The prepulse laser light 31P introduced into the chamber 2 is concentrated on the target misting region Rmist by the laser light concentrating optical system 22. The droplet target 27 supplied to the target misted region Rmist is irradiated with the prepulse laser light 31P concentrated on the target misting region Rmist, and the mist-like target 274 is generated.

The target image imaging unit 60 generates image data in which the mist-like target 274 is imaged, and transmits the image data to the CPU 8C. The CPU 8C controls, based on the image data, the stages of the high reflection mirror 331P and the combiner 332 and the manipulator 224 of the laser light concentrating optical system 22, thereby controlling the irradiation position of the prepulse laser light 31P, so that the mist-like target 274 having a predetermined shape is generated.

Further, the target image imaging unit 60 controls the output of the prepulse laser device 3P as follows so that the mist-like target 274 having a predetermined shape is generated.

The prepulse laser light 31P reflected by the beam splitter 500P enters the laser light sensor 501P, and a detection signal is generated. The detection signal is transmitted to the CPU 8C, and the CPU 8C controls, based on the detection signal, the prepulse laser device 3P so that the energy of the reflected prepulse laser light 31P becomes a predetermined energy. Since transmittance of the beam splitter 500P is known, the CPU 8C controls the energy of the reflected prepulse laser light 31P so that the energy of the transmitted prepulse laser light 31P becomes a predetermined value.

In step S140, the CPU 8C determines whether or not the mist-like target 274 having the predetermined shape is generated. In the determination of step S140, when the CPU 8C determines that the mist-like target 274 having the predetermined shape is not generated, the process of step S140 is repeated. In the determination of step S140, when the CPU 8C determines that the mist-like target 274 having the predetermined shape is generated, processing proceeds to step S150.

In step S150, the CPU 8C starts control of the main pulse laser device 3M. That is, the CPU 8C activates the main pulse laser device 3M, the stages of the high reflection mirror 331M and the like, and the EUV light sensors 43, and starts the following control.

The CPU 8C transmits a trigger signal that triggers the output of the main pulse laser light 31M to the main pulse laser device 3M at a timing obtained by adding a delay time Tdm to the delay time Tdp, and causes the main pulse laser device 3M to output the main pulse laser light 31M.

The delay time Tdm is a time for matching the timing at which the main pulse laser light is concentrated on the plasma generation region R1 with the timing at which the mist-like target 274 has moved to the plasma generation region R1. The delay time Tdm defines a timing at which the mist-like target 274 is irradiated with the main pulse laser light 31M. The delay time Tdm is a time calculated by the CPU 8C from the distance between the plasma generation region R1 and the target misting region Rmist and the frequency of the target detection signal.

The main pulse laser light 31M is reflected by the high reflection mirrors 331M, 332M of the laser light transmission optical system 33, is transmitted through the combiner 332 and the window 215, and is introduced into the chamber 2. The main pulse laser light 31M introduced into the chamber 2 is concentrated by the laser light concentrating optical system 22 on the mist-like target 274 in the plasma generation region R1. The mist-like target 274 is turned into plasma, and the EUV light 277 is emitted.

The plurality of EUV light sensors 43a to 43c transmit detection signals of the EUV light 277 to the CPU 8C. The CPU 8C calculates the pulse energy of the EUV light 277 from the detection signals. The CPU 8C controls the stages of the high reflection mirrors 331M, 332M to control the irradiation position of the main pulse laser light 31M so that the calculated value becomes the target value of the pulse energy of the EUV light 277. Further, the CPU 8C controls the output of the main pulse laser device 3M so that the pulse energy of the EUV light 277 becomes the target value.

The main pulse laser light 31M reflected by the beam splitter 500M enters the laser light sensor 501M, and a detection signal is generated. The detection signal is transmitted to the CPU 8C, and the CPU 8C controls, based on the detection signal, the main pulse laser device 3M so that the energy of the reflected main pulse laser light 31M becomes a predetermined energy. Since transmittance of the beam splitter 500M is known, the CPU 8C controls the energy of the reflected main pulse laser light 31M so that the energy of the transmitted main pulse laser light 31M becomes a predetermined value. The laser light sensor 501M is an example of the “pulse laser light sensor” in the present disclosure.

To improve the stability of the pulse energy of the EUV light 277, the CPU 8C controls the irradiation position of the main pulse laser light 31M on the mist-like target 274 as follows.

The CPU 8C calculates the centroid position of the EUV light 277 emitted from the plasma generation region R1. The centroid position of the EUV light 277 is obtained as follows.

The CPU 8C transmits a first gate signal to each of the plurality of EUV light sensors 43a to 43c at a timing delayed by a predetermined delay time from the timing at which the target detection signal is generated. The first gate signal is a signal that triggers the EUV light sensors 43a to 43c to measure the energy of the EUV light 277. Upon receiving the first gate signal, the EUV light sensors 43a to 43c measure the energy of the EUV light 277 and transmit the measurement values to the CPU 8C. The CPU 8C calculates the centroid position of the EUV light 277 a using predetermined algorithm.

The CPU 8C controls the stages of the high reflection mirrors 331M, 332M based on the calculated centroid position to control the irradiation position of the main pulse laser light 31M on the mist-like target 274 so that the EUV light 277 having a stable pulse energy is generated. Here, the control amount may be a control amount determined in advance according to a relative position of the centroid position with respect to the concentration position of the main pulse laser light 31M.

The CPU 8C generates log data indicating the relative position of the mist-like target 274 with respect to the concentrating position of the main pulse laser light 31M, and records the log data in the memory 8M.

In step S160, the CPU 8C determines whether or not the EUV light 277 having the target pulse energy is generated. In the determination of step S160, when the CPU 8C determines that the EUV light 277 having the target pulse energy is not generated, the process of step S160 is repeated. In the determination of step S160, when the CPU 8C determines that the EUV light 277 having the target pulse energy is generated, the flowchart of FIG. 7 is ended, and processing returns to the flowchart of FIG. 6.

### Detailed Description of Step S20 and Step S40

For monitoring the stability of the EUV light 277, an EUV pulse energy variation 3σe indicating a temporal variation of the EUV pulse energy may be used as the index. The EUV pulse energy variation 3σe is defined by, for example, the following expression.

EUV pulse energy variation 3σe[%]=(3σse/μe)×100

Here, σse is a standard deviation of the EUV pulse energy for a plurality of EUV pulses included in a unit time. Further, μe is an average value of the EUV pulse energy for a plurality of EUV pulses included in the unit time. The pulse energy of the EUV light 277 used for calculating the EUV pulse energy variation 3σe may be, for example, the sum or average of the measurement values of the EUV energy by the EUV light sensors 43a to 43c. The unit time is several seconds, for example, about 1 to 5 seconds. Here, as the index for evaluating the stability of the EUV pulse energy, for example, n times of the standard deviation σse may be used as an index instead of the EUV pulse energy variation 3σe.

When the EUV pulse energy variation 3σe deviates from an allowable range, the CPU 8C determines that the EUV light 277 is unstable and that some kind of abnormality has occurred in the EUV light generation system 1.

### Detailed Description of Step S60

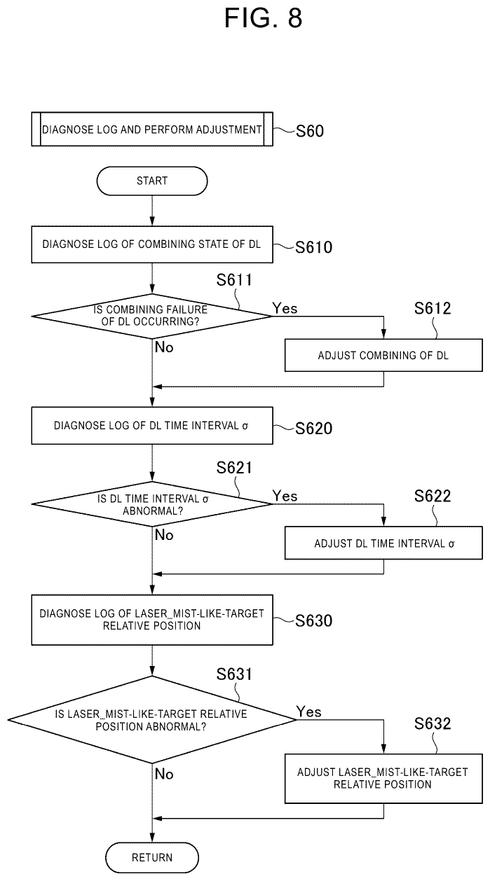

FIG. 8 is a flowchart showing details of processing applied to step S60 of FIG. 6. In step S60, the CPU 8C diagnoses log data including data prior to the time at which stability abnormality occurred, and finely adjusts a related configuration so that the pulse energy of the EUV light 277 returns to a stable state based on the diagnosis result.

In step S610, the CPU 8C diagnoses a log of the combining state of the droplet target 27. The notation “DL” in FIG. 8 means a droplet. The droplet implies the droplet target 27.

In step S611, the CPU 8C determines whether or not combining failure of the droplet target 27 is occurring. When it is determined that the droplet target 27 combining failure of the droplet target 27 is occurring as a result of the determination of step S611, processing proceeds to step S612.

In step S612, the CPU 8C adjusts a configuration related to combining failure of the droplet target 27. The configuration related to combining failure includes the piezoelectric element 255. After adjustment in step S612, processing proceeds to step S620.

Further, when it is determined that combining failure of the droplet target 27 is not occurring (when it is determined that the combining state is normal) as a result of the determination of step S611, processing proceeds to step S620.

In step S620, the CPU 8C diagnoses a log of the variation σ of the time interval of the droplet target 27 continuously supplied to the target misting region Rmist. The variation σ of the time interval of the droplet target 27 is also referred to as a time interval σ of the droplet target 27, and is represented as a “DL time interval σ” in FIG. 8.

In step S621, the CPU 8C determines whether or not the variation σ of the time interval of the droplet target 27 is abnormal. When it is determined that the variation σ of the time interval of the droplet target 27 is abnormal as a result of the determination of step S621, processing proceeds to step S622.

In step S622, the CPU 8C adjusts a configuration related to the variation σ of the time interval of the droplet target 27. The configuration related to the variation σ of the time interval includes the piezoelectric element 255. After adjustment in step S622, processing proceeds to step S630.

Further, when it is determined that there is no abnormality in the variation σ of the time interval of the droplet target 27 (when it is determined that the variation σ of the time interval is normal) as a result of the determination of step S621, processing proceeds to step S630.

In step S630, the CPU 8C diagnoses a relative concentration position of the main pulse laser light 31M radiated on the mist-like target 274. Hereinafter, the relative positional relation between the concentration position of the main pulse laser light 31M radiated to the mist-like target 274 and the mist-like target 274 is referred to as a “laser_mist-like-target relative position.”

In step S631, the CPU 8C determines whether or not the laser_mist-like-target relative position is abnormal. When it is determined that the laser_mist-like-target relative position is abnormal as a result of the determination of step S631, processing proceeds to step S632.

In step S632, the CPU 8C adjusts a configuration related to the laser_mist-like-target relative position. The configuration related to the laser_mist target-relative position includes the stages of the high reflection mirror 331M and the high reflection mirror 332M. After adjustment in step S632, the flowchart of FIG. 8 is ended, and processing returns to the flowchart of FIG. 6.

Further, when it is determined that there is no abnormality in the laser_mist-like-target relative position (when it is determined that the laser_mist-like-target relative position is normal) as a result of the determination of step S631, the flowchart of FIG. 8 is ended, and processing returns to the flowchart of FIG. 6.

### 2. PROBLEM

Even when the components of the EUV light generation system 1 are operating normally, abnormality may occur in the stability of the EUV light 277. It is empirically known that a main factor causing abnormality in the stability of the EUV light 277 is any one of abnormality in the combining state of the droplet target 27, abnormality in the time interval σ of the droplet target 27, and abnormality in the laser_mist-like-target relative position.

However, in step S40 of FIG. 6, it is difficult for a user to immediately determine which is the factor when it is determined that there is abnormality in the stability of the EUV light 277. Therefore, the user executes a special diagnosis program optimized for each factor, and adjusts a specific configuration based on the diagnosis result. Such a method requires execution of all diagnosis programs corresponding to the respective factors, and thus requires time to return to a state in which the EUV light 277 is stably generated.

### 3. FIRST EMBODIMENT

### 3.1 Configuration

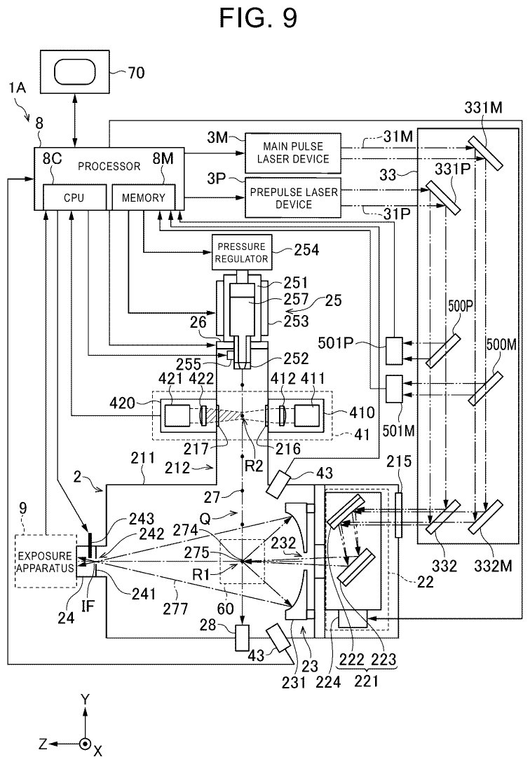

FIG. 9 is a view showing an EUV light generation system 1A according to a first embodiment. The EUV light generation system 1A will be described in terms of differences from the comparative example shown in FIG. 1.

In the EUV light generation system 1A, the memory 8M of the processor 8 stores a learning model to be used in a process of estimating a factor of the abnormal stability of the EUV light 277. The learning model is a learned learning model configured by a neural network created by performing machine learning using teacher data so as to output the factor of the abnormal stability of the EUV light 277 by inputting the respective log data of the pulse energy of the main pulse laser light 31M output from the main pulse laser device 3M, the EUV light pulse energy detected by each of the EUV light sensors 43a to 43c, and the irradiation pulse interval of the main pulse laser light 31M. The learning model is, in substance, a program.

Factors causing abnormality in the stability of the EUV light 277 include at least abnormality in the combining state of the droplet target 27, abnormality in the time interval σ of the droplet target 27, and abnormality in the laser_mist-like-target relative position.

A terminal 70 is connected to the processor 8. The terminal 70 has a function of storing the learning model in the memory 8M and a function of displaying a factor estimated by the learning model.

### 3.2 Operation

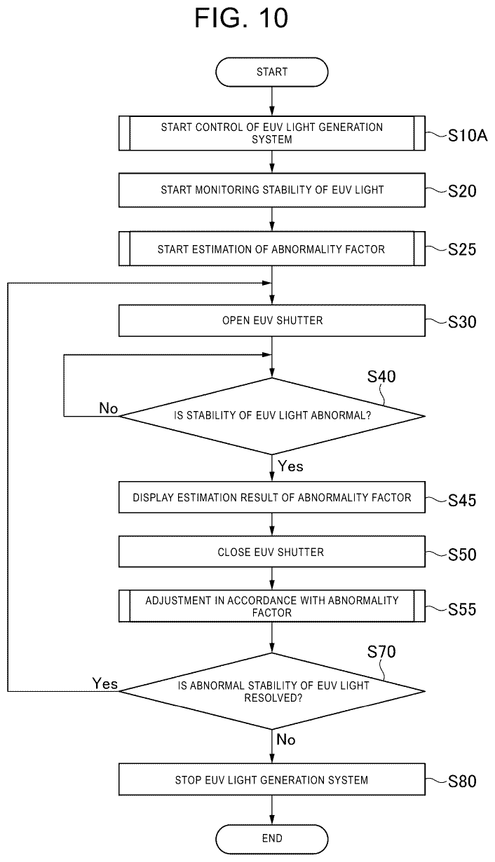

FIG. 10 is a flowchart showing an example of operation of the EUV light generation system 1A according to the first embodiment. The flowchart shown in FIG. 10 will be described in terms of differences from that shown in FIG. 6.

In the flowchart of FIG. 10, step S10A is included in place of step S10, and step S25 is included between step S20 and step S30. Further, step S45 is included between step S40 and step S50, and step S55 is included in place of step S60.

In step S10A, in addition to the operation of step S10, generation of log data of the pulse energy of the main pulse laser light 31M output from the main pulse laser device 3M, the EUV light pulse energy detected by each of the EUV light sensors 43a to 43c, and the irradiation pulse interval of the main pulse laser light 31M is also started. Each log data is recorded in the memory 8M and updated.

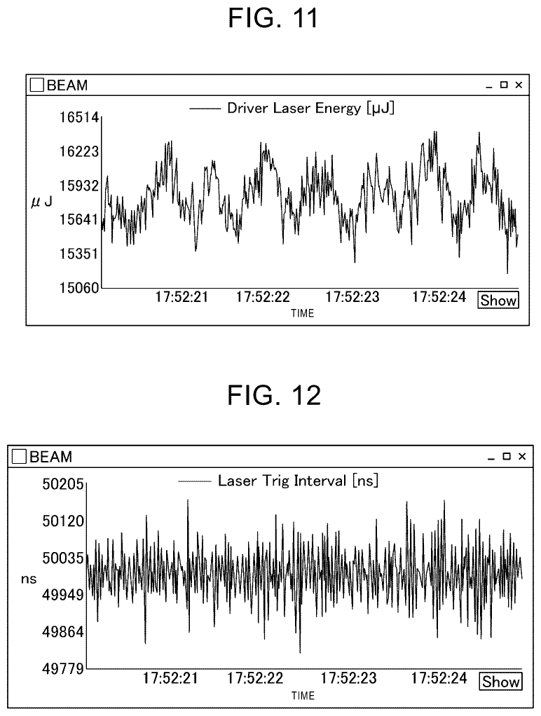

These three types of log data are data that can be graphed as shown in FIGS. 11 to 13. FIG. 11 is a graph showing an example of log data of the pulse energy of the main pulse laser light 31M.

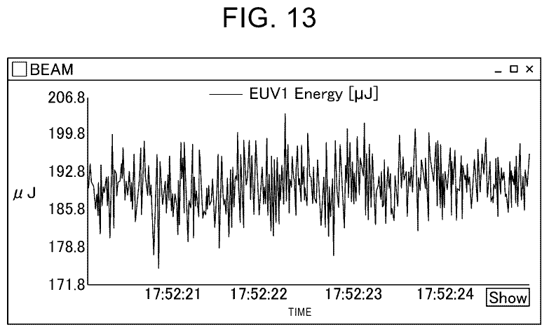

FIG. 12 is a graph showing an example of log data of the irradiation pulse interval of the main pulse laser light 31M. The irradiation pulse interval of the main pulse laser light 31M is a time interval between a passage timing of one preceding target through the target detection region R2 and a passage timing of one subsequent target through the target detection region R2. FIG. 13 is a graph showing an example of log data of the EUV light pulse energy detected by one of the EUV light sensors 43a to 43c (e.g., the EUV light sensor 43a).

The horizontal axis of each log data shown in FIGS. 11 to 13 is time. The time interval at which data is recorded may be different for each log data, but the range of time at which each log data is recorded is set to be the same for each log data. The time range is set so as to allow trace back to 3 to 8 seconds from the current time. The number of pieces of data capable of being traced back in each log data may be 500 to 1500 from the latest. When the number of pieces of data to be recorded is different for each log data, the number of pieces of data is adjusted, for example, by zero padding or the like so that the number of pieces of data of each log data becomes the same.

In step S25, the CPU 8C inputs the three types of log data in which generation is started in step S10A into a learned learning model configured by a neural network, and starts estimation of the factor of the abnormal stability of the EUV light 277. Details of step S25 will be described later.

When it is determined that abnormality is occurring in the stability of the EUV light 277 as a result of the determination of step S40, processing proceeds to step S45. In step S45, the CPU 8C displays an estimation result of the abnormality factor on the terminal 70. A relative value indicating a probability of occurrence is displayed on the terminal 70 for each of abnormality in the combining state of the droplet target 27, abnormality in the time interval σ of the droplet target 27, and abnormality in the laser_mist-like-target relative position. Details of a display example of the estimation result on the terminal 70 will be described later.

In step S55, the CPU 8C finely adjusts the configuration related to the most probable occurring abnormality factor so that the stability of the pulse energy of the EUV light 277 returns to the predetermined value. Details of step S55 will be described later. After the fine adjustment, the CPU 8C continues to detect the EUV light 277 until log data that enables determination of the stability is accumulated.

After step S55, processing proceeds to step S70. Other steps may be similar to those in FIG. 6.

### Detailed Description of Step S25

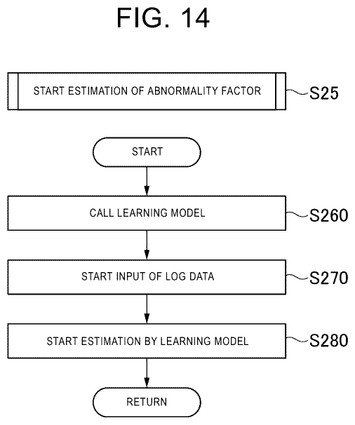

FIG. 14 is a flowchart showing details of processing applied to step S25.

In step S260, the CPU 8C calls the learning model stored in the memory 8M.

In step S270, the CPU 8C inputs the following three types of log data (1) to (3) stored in the memory 8M into the learning model.
(1) The pulse energy of the main pulse laser light 31M output from the main pulse laser device 3M
(2) The irradiation pulse interval of the main pulse laser light 31M
(3) The EUV light pulse energy detected by each of the EUV light sensors 43a to 43c

In step S280, the CPU 8C performs operation by the learning model and estimates the abnormality factor. The estimation is performed, for example, every second, and the CPU 8C records the estimation result at every estimated time in the memory 8M.

After step S280, the flowchart of FIG. 14 is ended, and processing returns to the flowchart of FIG. 10.

### Detailed Description of Step S45

In step S45, the CPU 8C displays the estimation result of the abnormality factor on the terminal 70 and identifies the most probable abnormal state. When the CPU 8C determines that there is abnormality in the stability of the EUV light 277 in step S40, the estimation result at the time closest to the determination time among the estimation results accumulated in the memory 8M is called from the memory 8M and displayed on the terminal 70.

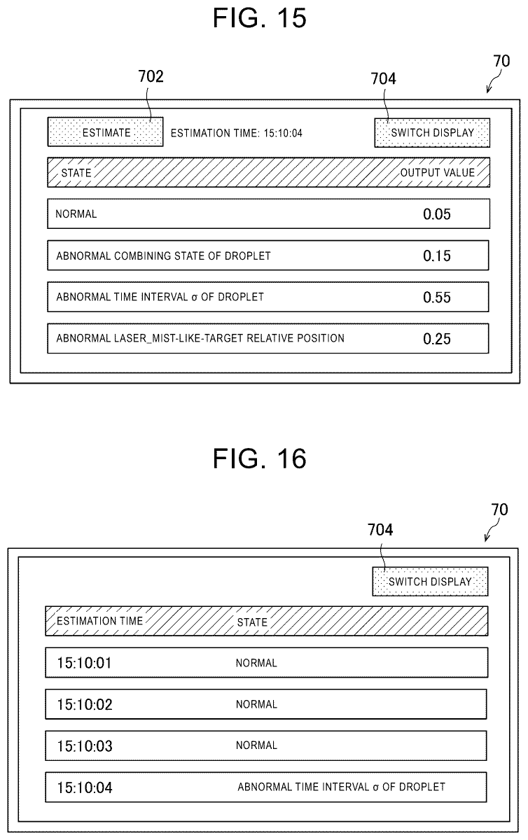

FIG. 15 is a diagram showing display example 1 of the estimation result on the terminal 70. FIG. 16 is a diagram showing display example 2 on the terminal 70. In FIG. 15, the estimation results of all states at the time when an estimation button 702 is pressed are represented by probabilities. As shown in FIG. 15, as a result of estimation using the learning model, a numerical value indicating the probability of each state may be displayed as an output value for each of four states: “normal”, “abnormal combining state of droplet”, “abnormal time interval σ of droplet”, and “abnormal laser_mist-like-target relative position.” The output value indicating the probability of each state has a maximum value of 1 and a minimum value of 0. The output value of each state is a relative value, and the sum of the output values of all states is 1. Further, the time when the estimation button 702 was pressed is displayed as the estimation time.

When a display switch button 704 on the screen is pressed, the screen is switched to the display screen shown in FIG. 16, and transition of the estimation result for the last few seconds of the most probable state among the four states is displayed. When the display switch button 704 on the screen of FIG. 16 is pressed, the display screen is switched to the display screen shown in FIG. 15.

### Detailed Description of Step S55

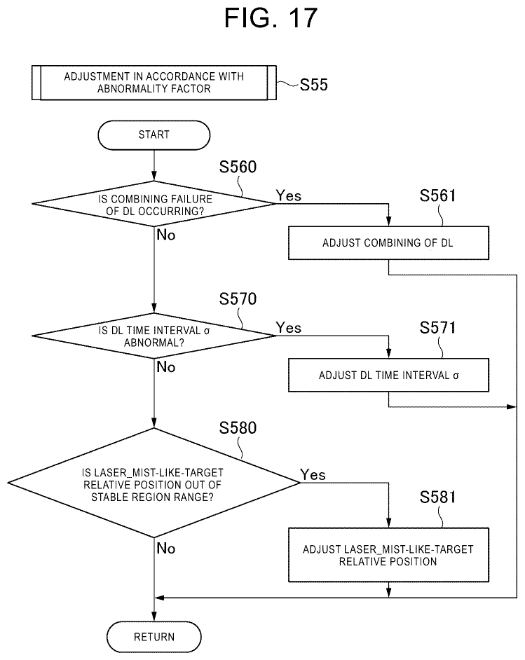

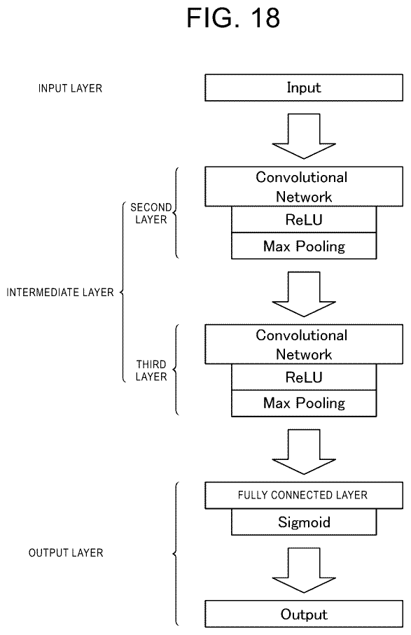

FIG. 17 is a flowchart showing details of processing applied to step S55. In step S55, the CPU 8C adjusts a particular configuration of the EUV light generation system 1A based on the estimation result in step S45.

In step S560, the CPU 8C determines whether or not combining failure of the droplet target 27 is occurring. When it is determined that the droplet target 27 combining failure of the droplet target 27 is occurring as a result of the determination of step S560, processing proceeds to step S561. Step S561 is similar to step S612 of FIG. 12.

When it is determined that combining failure of the droplet target 27 is not occurring as a result of the determination of step S560, processing proceeds to step S570. In step S570, the CPU 8C determines whether or not the droplet time interval σ is abnormal. When it is determined that the droplet time interval σ is abnormal as a result of the determination of step S570, processing proceeds to step S571. Step S571 is similar to step S622 of FIG. 8.

When it is determined that the droplet time interval σ is not abnormal as a result of the determination of step S570, processing proceeds to step S580. In step S580, the CPU 8C determines whether or not the laser_mist-like-target relative position is within a stable region range. When it is determined that the laser_mist-like-target relative position is outside the stable region range, that is, when it is determined that the laser_mist-like-target relative position is abnormal as a result of the determination of step S580, processing proceeds to step S581. Step S581 is similar to step S632 of FIG. 12. After step S561, step S571, or step S581, the flowchart of FIG. 17 is ended, and processing returns to the flowchart of FIG. 10.

Further, when it is determined that the laser_mist-like-target relative position is within the stable region range as a result of the determination of step S580, the flowchart of FIG. 17 is ended, and processing returns to the flowchart of FIG. 10.

Here, in FIG. 17, steps S560, S570, and S580 are shown in a stepwise manner for convenience of explanation, but since the most probable abnormality factor is estimated by estimation using the learning model (step S45), the determination of steps S560, S570, and S580 can be collectively performed by applying the most probable abnormality factor indicated by the estimation result by the learning model.

That is, since the most probable abnormality factor is estimated in step S45 of FIG. 10, the process performed in step S55 is any one of a droplet combining adjustment (step S561), a droplet interval adjustment (step S571), and a laser_mist-like-target relative position adjustment (step S581) corresponding to the most probable abnormality factor. Therefore, the diagnosis programs for all factors are not executed as in the comparative example (FIG. 8).

### 3.3 Generation Method of Learning Model

### 3.3.1 Configuration of Learning Model

FIG. 18 is a diagram showing the learning model used in the first embodiment. The learning model is configured by a deep neural network.

The learning model includes an input layer, intermediate layers, and an output layer. Following the input layer, which is a first layer, a convolutional layer including a convolutional network, an activation function, and pooling is arranged in the second and the third layers as the intermediate layers. A ReLU function is used as the activation function of the intermediate layers to improve the learning efficiency. Max pooling is applied to the pooling. A fully connected layer and an activation function are arranged in the output layer. A sigmoid function is used as the activation function of the output layer.

The convolutional network of each of the second and third layers performs feature detection. The fully connected layer of the output layer performs feature summarization and output of a final inference result.

### 3.3.2 Generation Flow of Learning Model

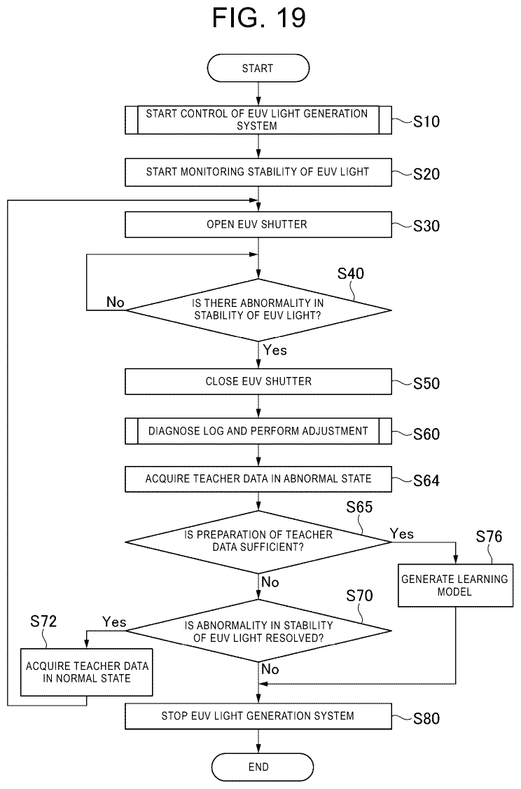

FIG. 19 is a flowchart showing a generation method of the learning model. The flowchart of FIG. 19 will be described in terms of differences from the flowchart of FIG. 6. It is assumed that the learning model shown in FIG. 18 is stored in the memory 8M.

In the flowchart of FIG. 19, step S64, step S65, and step S76 are included between step S60 and step S80 of FIG. 6, and step S72 is included in the middle of returning from step S70 to step S30.

In step S64 after step S60, the CPU 8C records, in the memory 8M, combinations of log data (1) to (3) in the following three abnormal states [1] to [3] diagnosed in step S60 as teacher data in the abnormal state. The teacher data in the abnormal state is an example of “second teacher data” in the present disclosure.
[1] Abnormal combining state of droplet target 27
[2] Abnormal time interval σ of droplet target 27
[3] Abnormal laser_mist-like target relative position

That is, the combination of the log data (1) to (3) identified as any one of the three abnormal states is recorded as the teacher data of the abnormal state. The teacher data may be understood as training data for training the learning model.

In step S65, the CPU 8C determines whether or not preparation of the teacher data required for learning is sufficient. In machine learning for generating a learning model, it is required to prepare a data set for learning including a large number of pieces of teacher data in the abnormal state and teacher data in the normal state. For example, the number of pieces of teacher data in the abnormal state and the number of pieces of teacher data in the normal state required for learning in order to realize a desired inference performance are set in the CPU 8C, and the CPU 8C determines whether or not the number of pieces of the collected teacher data satisfies the set condition.

When the preparation of the teacher data is not sufficient and the determination result of step S65 is No, processing proceeds to step S70.

When the determination result of step S70 is Yes, the CPU 8C proceeds to step S72.

In step S72, the CPU 8C stores the log data (1) to (3) in the normal state in the memory 8M as the teacher data in the normal state. The teacher data in the normal state is an example of the “first teacher data” in the present disclosure.

After step S72, the CPU 8C returns to step S30.

When the determination result of step S65 is Yes, that is, when both of the teacher data in the abnormal state and the teacher data in the normal state are sufficient, processing proceeds to step S76.

In step S76, the CPU 8C calls the learning model of FIG. 18 from the memory 8M, inputs all of the teacher data into the learning model to cause learning, and causes the memory 8M to store the learned model.

The log data input to the learning model includes the following three types (1) to (3).
(1) The pulse energy of the main pulse laser light 31M output from the main pulse laser device 3M
(2) The irradiation pulse interval of the main pulse laser light 31M
(3) The EUV light pulse energies detected by each of the EUV light sensors 43a to 43c

The learning model is constructed as a four-class classification model that uses the three types of log data (1) to (3) described above as input data, estimates which state the EUV light generation system 1A is in among the four states, and outputs a score (output value) indicating the probability of being in each of the four states. That is, the learned model is a neural network learned by using the teacher data in which each of the four states is associated with a set of three types of log data (1) to (3). The output value indicating the probability of each state is an example of output data output from the learning model. After generating the learned model, processing may proceed to step S10A of FIG. 10.

### 3.4 Modification

The generation of the learning model described in step S76 is not limited to the configuration performed by the CPU 8C. For example, the process of step S76 may be executed using an information processing device including a CPU different from the CPU 8C. In this case, the CPU of the different information processing device may receive the teacher data and generate the learned model.

Further, the collection of the teacher data and the generation of the learning model (processing of machine learning) are not required to be executed continuously, and the collection of the teacher data and the generation of the learning model may be executed separately in time.

### 3.5 Effect

According to the EUV light generation system 1A of the embodiment, when abnormality occurs in the stability of the EUV light 277, since the factor thereof is identified using the learning model, time until the EUV light generation system 1A is returned from the abnormal state is shorter than that of the comparative example.

### 4. EXPOSURE APPARATUS AND INSPECTION APPARATUS

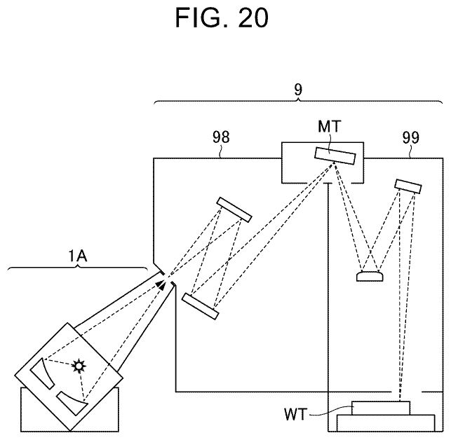

FIG. 20 schematically shows the configuration of the exposure apparatus 9 connected to the EUV light generation system 1A.

In FIG. 20, the exposure apparatus 9 as the external apparatus includes a mask irradiation unit 98 and a workpiece irradiation unit 99. The mask irradiation unit 98 illuminates, via a reflection optical system, a mask pattern of a mask table MT with the EUV light 277 incident from the EUV light generation system 1A. The workpiece irradiation unit 99 images the EUV light 277 reflected by the mask table MT onto a workpiece (not shown) placed on the workpiece table WT via a reflection optical system. The workpiece is a photosensitive substrate such as a semiconductor wafer on which photoresist is applied. The exposure apparatus 9 synchronously translates the mask table MT and the workpiece table WT to expose the workpiece to the EUV light 277 reflecting the mask pattern. Through the exposure process as described above, a device pattern is transferred onto the semiconductor wafer, thereby an electronic device can be manufactured.

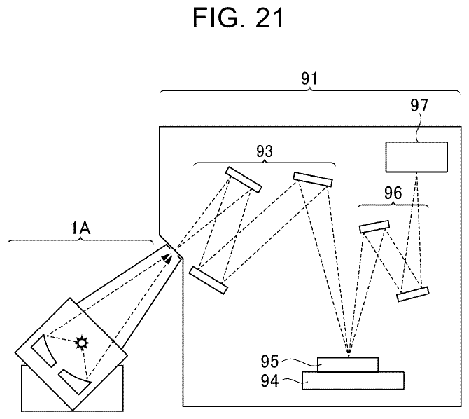

An inspection apparatus 91 may be connected to the EUV light generation system 1A as the external apparatus instead of the exposure apparatus 9. FIG. 21 schematically shows the configuration of the inspection apparatus 91 connected to the EUV light generation system 1A.

In FIG. 21, the inspection apparatus 91 as the external apparatus includes an illumination optical system 93 and a detection optical system 96. The illumination optical system 93 reflects the EUV light 277 incident from the EUV light generation system 1 to illuminate a mask 95 placed on a mask stage 94. Here, the mask 95 conceptually includes a mask blanks before a pattern is formed. The detection optical system 96 reflects the EUV light 277 from the illuminated mask 95 and forms an image on a light receiving surface of a detector 97. The detector 97 having received the EUV light 277 obtains an image of the mask 95. The detector 97 is, for example, a time delay integration (TDI) camera. A defect of the mask 95 is inspected based on the image of the mask 95 acquired by the above-described process, and a mask suitable for manufacturing an electronic device is selected using the inspection result. Then, the electronic device can be manufactured by exposing and transferring the pattern formed on the selected mask onto the photosensitive substrate using the exposure apparatus 9.

### 5. OTHERS

The description above is intended to be illustrative and the present disclosure is not limited thereto. Therefore, it would be obvious to those skilled in the art that various modifications to the embodiment of the present disclosure would be possible without departing from the spirit and the scope of the appended claims. Further, it would be also obvious to those skilled in the art that the embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. An extreme ultraviolet light generation system configured to generate a mist-like target by irradiating, with prepulse laser light, a droplet target generated by combining a plurality of droplets, cause plasma to be generated by irradiating the mist-like target with main pulse laser light, and generate extreme ultraviolet light, the extreme ultraviolet light generation system comprising:
a pulse laser light sensor configured to measure a pulse energy of the main pulse laser light;
a target detection sensor configured to generate a passage signal of the droplet target for generating a trigger signal for irradiation with the main pulse laser light;
an EUV light sensor configured to measure a pulse energy of the extreme ultraviolet light; and
a processor,
the processor including a neural network which receives, as input data, log data of the pulse energy obtained from the pulse laser light sensor, log data of an irradiation pulse interval of the main pulse laser light, and log data of the pulse energy obtained from the EUV light sensor and generates, as output data, information enabling to identify which state the extreme ultraviolet light generation system is in among a normal state, a state in which combining failure of the droplet targets is occurring, a state in which a variation of intervals between the droplet targets is abnormal, and a state in which a relative position between an irradiation position with the main pulse laser light and the mist-like target is abnormal.

2. The extreme ultraviolet light generation system according to claim 1,
further comprising a terminal configured to display the information.

3. The extreme ultraviolet light generation system according to claim 2,
wherein the terminal displays output values indicating probabilities of being in the states for each state.

4. The extreme ultraviolet light generation system according to claim 3,
wherein the output values are relative values in a numerical range in which 1 is a maximum value and 0 is a minimum value, and
a sum of the output values of the respective states is 1.

5. The extreme ultraviolet light generation system according to claim 2,
wherein the processor executes a process of estimating which state the extreme ultraviolet light generation system is in using the neural network at s specific time interval, and
the terminal displays, for each estimation time, a state with the output value being maximum.

6. The extreme ultraviolet light generation system according to claim 1,
wherein the respective log data are measured in a same time period.

7. The extreme ultraviolet light generation system according to claim 6,
wherein the time period is 3 to 8 seconds.

8. The extreme ultraviolet light generation system according to claim 7,
wherein a number of pieces of data in the time period of each log data is 500 to 1500.

9. The extreme ultraviolet light generation system according to claim 8,
wherein, when the number of pieces of data is different for each log data, the number of pieces of data of each log data is adjusted to be the same.

10. The extreme ultraviolet light generation system according to claim 8,
wherein the number of pieces of data in the time period of each log data is the same.

11. The extreme ultraviolet generation system according to claim 1,
wherein an intermediate layer of the neural network includes a convolutional network.

12. The extreme ultraviolet light generation system according to claim 1,
wherein an activation function of an intermediate layer of the neural network is a ReLU function.

13. The extreme ultraviolet light generation system according to claim 1,
wherein an intermediate layer of the neural network includes a process of max pooling.

14. The extreme ultraviolet light generation system according to claim 1,
wherein an output layer of the neural network includes a fully connected layer.

15. The extreme ultraviolet light generation system according to claim 14,
wherein an activation function of the output layer of the neural network is a sigmoid function.

16. The extreme ultraviolet light generation system according to claim 1,
wherein the neural network is a neural network learned by using teacher data in which the states and the log data are associated respectively.

17. The extreme ultraviolet light generation system according to claim 16,
wherein the teacher data includes first teacher data which is the log data when the extreme ultraviolet light generation system is in a normal state and second teacher data which is the log data when the extreme ultraviolet light generation system is in an abnormal state.

18. An electronic device manufacturing method, comprising:
generating extreme ultraviolet light using an extreme ultraviolet light generation system;
outputting the extreme ultraviolet light to an exposure apparatus; and
exposing a photosensitive substrate to the extreme ultraviolet light in the exposure apparatus to manufacture an electronic device,
the extreme ultraviolet light generation system being configured to generate a mist-like target by irradiating, with prepulse laser light, a droplet target generated by combining a plurality of droplets, cause plasma to be generated by irradiating the mist-like target with main pulse laser light, and generate the extreme ultraviolet light,
the extreme ultraviolet light generation system comprising a pulse laser light sensor configured to measure a pulse energy of the main pulse laser light, a target detection sensor configured to generate a passage signal of the droplet target for generating a trigger signal for irradiation with the main pulse laser light, an EUV light sensor configured to measure a pulse energy of the extreme ultraviolet light, and a processor, and
the processor including a neural network which receives, as input data, log data of the pulse energy obtained from the pulse laser light sensor, log data of an irradiation pulse interval of the main pulse laser light, and log data of the pulse energy obtained from the EUV light sensor and generates, as output data, information enabling to identify which state the extreme ultraviolet light generation system is in among a normal state, a state in which combining failure of the droplet targets is occurring, a state in which a variation of intervals between the droplet targets is abnormal, and a state in which a relative position between an irradiation position with the main pulse laser light and the mist-like target is abnormal.

19. An electronic device manufacturing method, comprising:
inspecting a defect of a mask by irradiating the mask with extreme ultraviolet light generated by an extreme ultraviolet light generation system;
selecting the mask using a result of the inspection; and
exposing and transferring a pattern formed on the selected mask onto a photosensitive substrate,
the extreme ultraviolet light generation system being configured to generate a mist-like target by irradiating, with prepulse laser light, a droplet target generated by combining a plurality of droplets, cause plasma to be generated by irradiating the mist-like target with main pulse laser light, and generate the extreme ultraviolet light,
the extreme ultraviolet light generation system comprising a pulse laser light sensor configured to measure a pulse energy of the main pulse laser light, a target detection sensor configured to generate a passage signal of the droplet target for generating a trigger signal for irradiation with the main pulse laser light, an EUV light sensor configured to measure a pulse energy of the extreme ultraviolet light, and a processor, and
the processor including a neural network which receives, as input data, log data of the pulse energy obtained from the pulse laser light sensor, log data of an irradiation pulse interval of the main pulse laser light, and log data of the pulse energy obtained from the EUV light sensor and generates, as output data, information enabling to identify which state the extreme ultraviolet light generation system is in among a normal state, a state in which combining failure of the droplet targets is occurring, a state in which a variation of intervals between the droplet targets is abnormal, and a state in which a relative position between an irradiation position with the main pulse laser light and the mist-like target is abnormal.
